(19) United States
(12) Patent Application Publication
(10) Pub. No.: US 2019/0279871 A1
(43) Pub. Date: Sep. 12, 2019

(54) METHOD OF ENHANCING GENERATION EFFICIENCY OF PATTERNED OPTICAL COATING

(71) Applicant: MORRISON OPTOELECTRONICS LTD., Hsin Chu Hsien (TW)

(72) Inventors: Wei-Kuo CHENG, Taipei City (TW); Chin-Chen KUO, Hsinchu City (TW); Tsung-Hsiu WU, Zhubei City (TW); Yun-Hui TAI, Hsinchu County (TW); Cheng-Hung CHEN, New Taipei City (TW)

(21) Appl. No.: 15/916,311

(22) Filed: Mar. 9, 2018

(51) Int. Cl. H01L 21/033; C23C 14/24; C23C 14/04; G03F 7/00; G03F 7/11; H01L 21/027

(52) U.S. Cl. CPC H01L 21/0337; C23C 14/24; H01L 21/0273; G03F 7/0035; G03F 7/11; C23C 14/042

(57) ABSTRACT

A method of enhancing generation efficiency of patterned optical coating is disclosed. When an exposure and development process is performed after a photoresist process on the silicon wafer, a dummy pattern is formed on a scribe line around a chip as a sacrificial layer. After an optical coating process is completed, the dummy pattern from the photoresist to be removed can be selected as the starting point of a photoresist lift-off process, such that the photoresist removal can be more efficient and accurate, and the generation efficiency of patterned optical coating is enhanced.

### BACKGROUND OF THE INVENTION

### Field of the Invention

The present invention relates to a method of enhancing generation efficiency of patterned optical coating, particularly to a method in which a dummy pattern s provided on a scribe line of silicon wafer as a sacrificial layer such that when the photoresist is removed, the dummy pattern closer to the photoresist to be removed is selected as the starting point of a photoresist lift-off process, and the photoresist removal is more efficient and reliable.

### Description of the Related Art

The technology of forming semiconductor component circuit using a patterned process and an etching process is widely known. When implemented, as shown in FIG. 1, it includes the following steps: (a) cleaning silicon wafer 11; (b) coating photoresist on the silicon wafer surface to form a photoresist layer 12; (c) exposure and development, irradiating a mask with UV light and projecting it onto the photoresist layer, so that the photoresist layer that is not in the predetermined range is damaged, and a predetermined circuit hole 13 is formed; (d) forming a circuit 14 on the circuit hole 13 of the silicon wafer by an etching process; and (e) removing photoresist: removing the photoresist layer 12 on the silicon wafer surface.

However, as shown in FIG. 2, since the surface of silicon wafer 11 is provided with a plurality of chips in a matrix arrangement, when the photoresist layer 12 is removed by the photoresist lift-off process, photoresist materials that are farther away from the silicon wafer 11 are often not easily removed because they are too far from the lift-off starting point, and require multiple procedures to remove them, seriously affecting the efficiency of patterned optical coatings.

### SUMMARY OF THE INVENTION

In view of the aforementioned shortcomings in the art, according to various manufacturing experiences and accumulated technology, after a long period of research in conjunction with improvement on the aforementioned deficiencies, a new method of enhancing generation efficiency of patterned optical coating according to the present invention is eventually presented by the inventor to eliminate the deficiencies generated in the prior art.

According to the method of enhancing generation efficiency of patterned optical coating in the present invention, after the photoresist process is perfumed on the silicon wafer surface, a dummy pattern is formed on the scribe line around the chip during the exposure and development process.

According to the method of enhancing generation efficiency of patterned optical coating in the present invention, the dummy pattern formed on the scribe line around the chip is a sacrificial layer that serves as a starting point for the photoresist lift-off process. This is a secondary objective of the present invention.

According to the method of enhancing generation efficiency of patterned optical coating in the present invention, since the dummy pattern that can serve as the starting point of the photoresist lift-off process is formed on the scribe line around each chip, when performing a photoresist lift-off process, one may choose to start from any dummy pattern which is close to the photoresist to be removed, so as to avoid a conventional problem that part of photoresist cannot be reliably removed. This is another objective of the present invention.

According to the method of enhancing generation efficiency of patterned optical coating in the present invention, the dummy pattern served as a sacrificial layer may be a grid pattern, a square pattern, a circle pattern, or a triangle pattern. This is another objective of the present invention.

According to the method of enhancing generation efficiency of patterned optical coating in the present invention, the width of the dummy pattern is preferably 1-80 μm. This is a further objective of the present invention.

The objective, shape, configuration means, characteristics and effects of the present invention will be apparent with reference to the following description in conjunction with the accompanying drawings.

### BRIEF DESCRIPTION OF THE DRAWINGS

FIG. 1 is a cross-sectional view showing a conventional semiconductor patterned process flow;

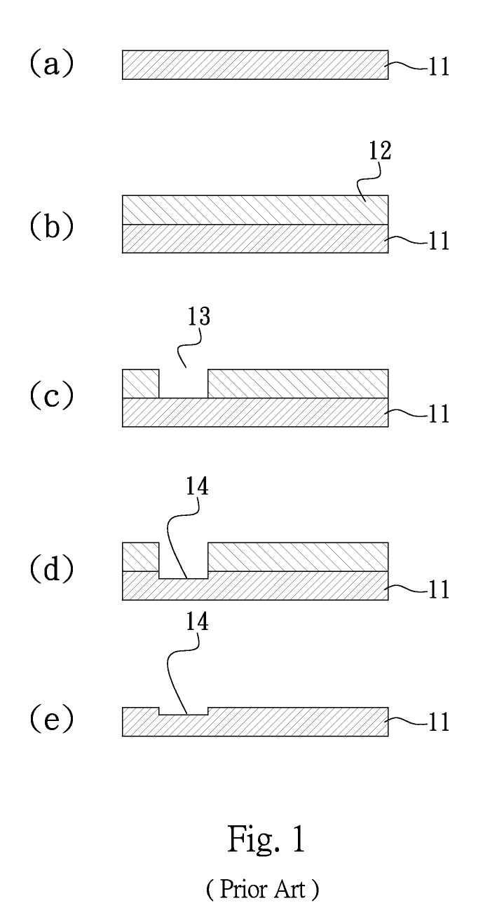

FIG. 2 is a schematic view showing a conventional silicon wafer coated with photoresist;

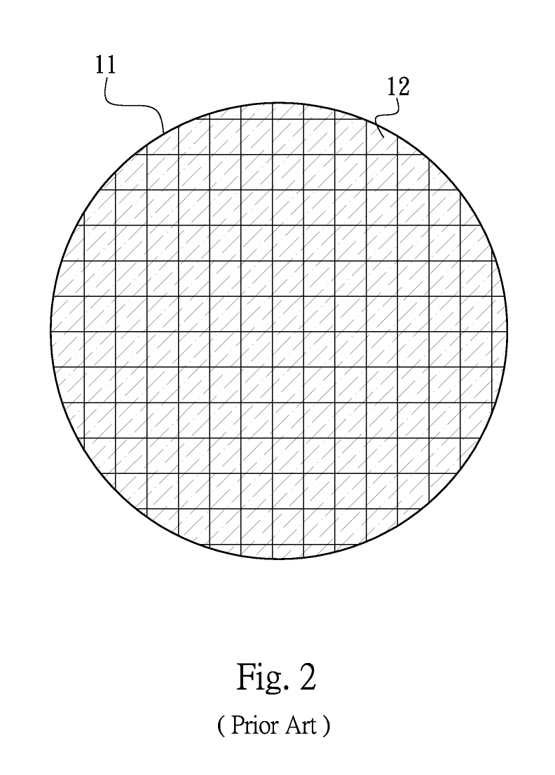

FIG. 3 is a flowchart showing steps in a method of enhancing generation efficiency of patterned optical coating according to the present invention;

FIG. 4 is a cross-sectional view showing the flow of the method of enhancing generation efficiency of patterned optical coating in the present invention;

FIG. 5 is a plan view of wafer configuration according to the method of enhancing generation efficiency of patterned optical coating in the present invention;

FIG. 6A is a plan view of silicon wafer according to the method of enhancing generation efficiency of patterned optical coating in the present invention;

FIG. 6B is an enlarged view showing part A of FIG. 6A;

FIG. 7 is a schematic diagram showing the dummy pattern in the method of enhancing generation efficiency of patterned optical coating according to the present invention is a grid pattern;

FIG. 8 is a schematic diagram showing the dummy pattern in the method of enhancing generation efficiency of patterned optical coating according to the present invention is a square pattern;

FIG. 9 is a schematic diagram showing the dummy pattern in the method of enhancing generation efficiency of patterned optical coating according to the present invention is a circle pattern; and

FIG. 10 is a schematic diagram showing the dummy pattern in the is method of enhancing generation efficiency of patterned optical coating according to the present invention is a triangle pattern.

### DETAILED DESCRIPTION OF THE PREFERRED EMBODIMENT

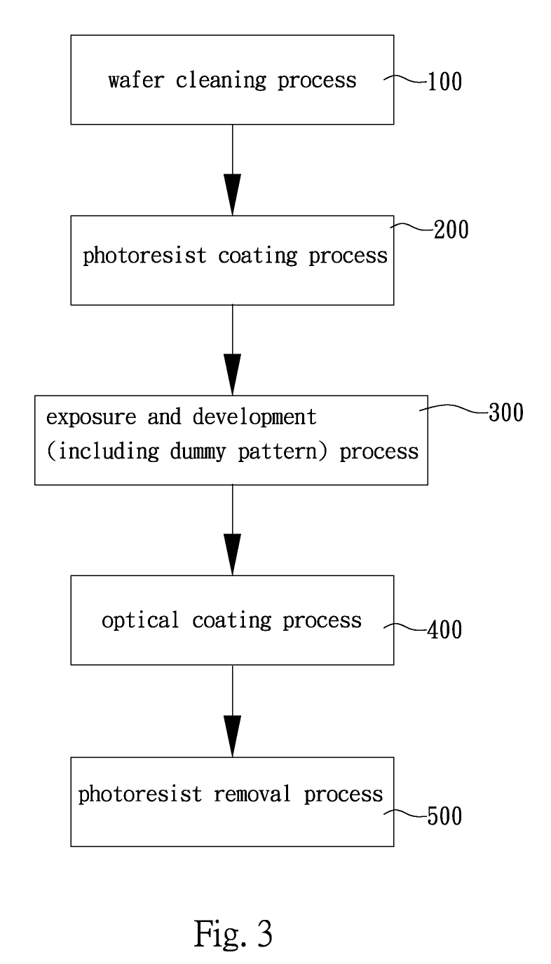

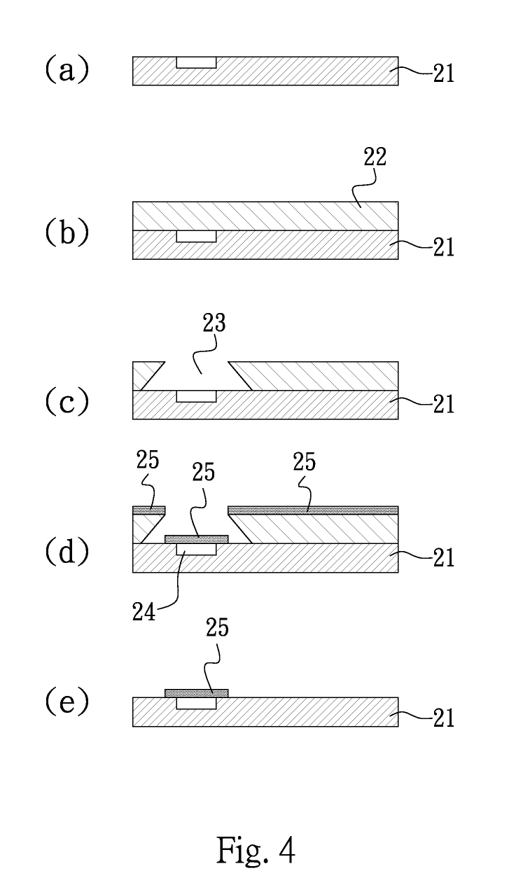

A method of enhancing generation efficiency of patterned optical coating in the present invention, as shown in FIGS. 3 and 4, includes: (a) wafer cleaning process 100: cleaning the surface of a silicon wafer 21; (b) photoresist coating process 200: using a spin coater for wafer vacuum suction, and then dropping a photoresist solution from above to form a photoresist layer 22 on the surface of the silicon wafer; (c) exposure and development (including dummy pattern) process 300: with an optical exposure system, irradiating a mask with UV light and then projecting it onto the photoresist layer, such that the chemical bonds of some photoresists are damaged, and a lens group in the optical exposure system projects the pattern on the mask onto the silicon wafer 21 to farm a line pattern 23 on the photoresist layer of the silicon wafer; (d) optical coating process 400: through an evaporation process, an optical film 25 is coated on the surface of the line pattern 23 and the exposed chip 24; and (e) photoresist removal process 500: using the photoresist solution to dissolve and remove the remaining photoresist on the silicon wafer so that the surface of the silicon wafer 21 only keeps the necessary optical film 25.

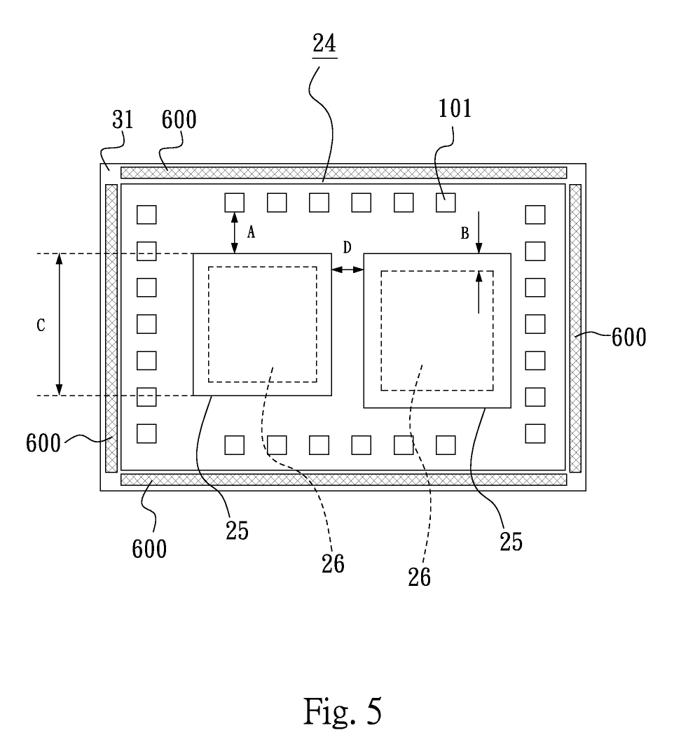

Please refer to FIG. 5. In the method of enhancing generation efficiency of patterned optical coating of the present invention, the outer of each chip 24 is provided with a scribe line 31, and at least one sensor 26 is provided inside the chip 24. The upper surface of each sensor 26 is coated with the optical film 25. After the optical film 25 is coated, each chip 24 is separated by the scribe line 31, and the optical film 25 coated on the chip 24 is sized to be within the specification. For example, the distance (A) between the optical film 25 and the pad 101 should be equal to or greater than 80 μm, the width (B) of the reaction region within the optical film 25 should be equal to or greater than 50 μm, the width (C) of the optical film 25 should be equal to or greater than 100 μm, and the gap (D) between the two optical films 25 should be equal to or greater than 50 μm, etc.

As shown, in the method of enhancing generation efficiency of patterned optical coating of the present invention, a dummy pattern 600 is formed on the scribe line 31 around the chip 24. The dummy pattern 600 is formed on the scribe line 31 simultaneously with the exposure and development (including dummy pattern) process 300. The dummy pattern 600 may be formed in different line types, mainly served as a sacrificial layer.

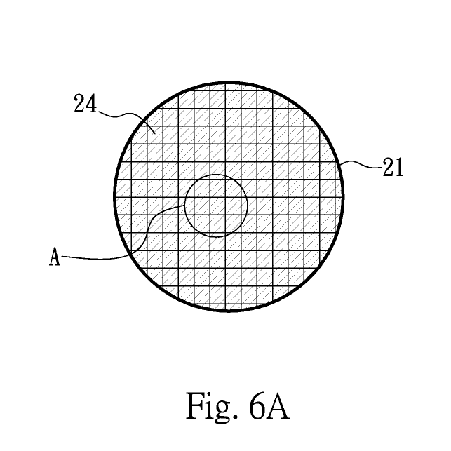

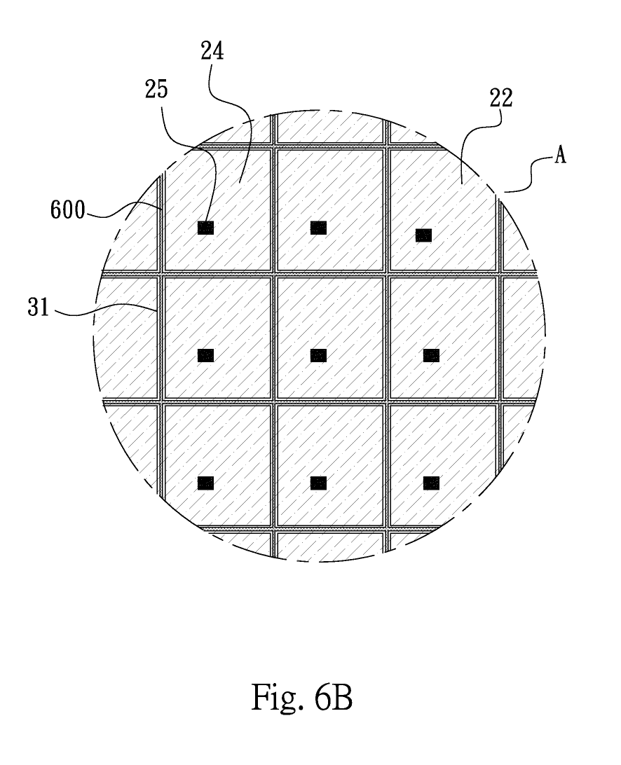

Please refer to FIGS. 6A and 6B. When the photoresist layer 22 is removed by a photoresist lift-off process after each chip on the silicon wafer 21 is coated with the optical film 25, any dummy pattern 600 provided on the scribe line 31 may be used as a lift-off start point, removing the photoresist around the optical film 25 nearby so that the photoresist at any position can be reliably removed in one operation.

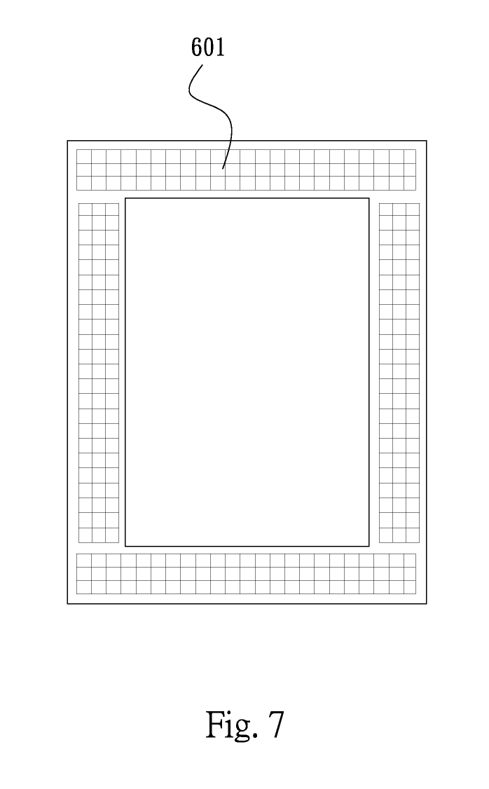

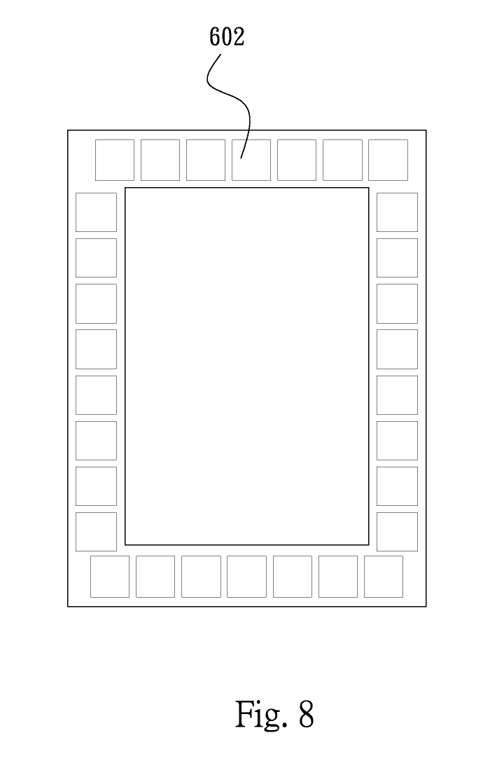

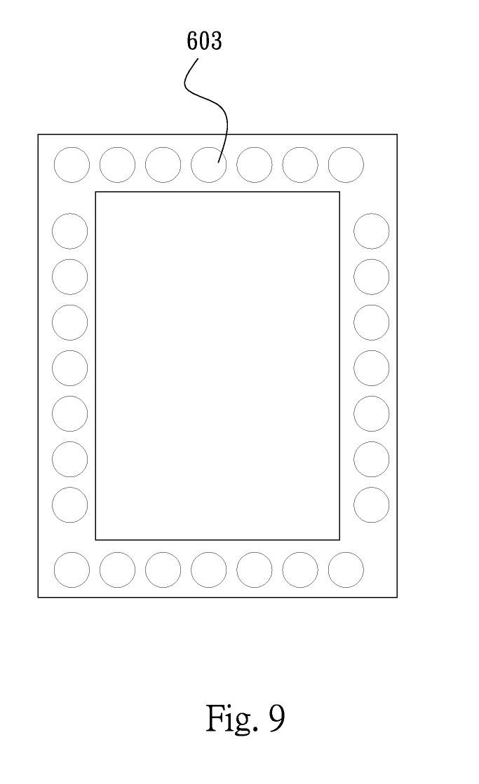

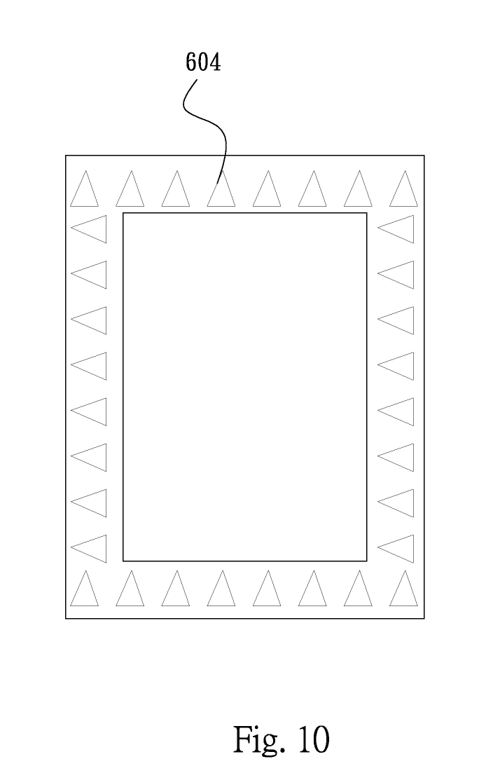

According to the method of enhancing generation efficiency of patterned optical coating in the present invention, the type of the dummy pattern 600 can be a grid pattern 601. (as shown in FIG. 7), a square pattern 602 (as shown in FIG. 8), a circle pattern 603 (as shown in FIG. 9), a triangle pattern 604 (as shown in FIG. 10) or other patterns. The width of the dummy pattern 600 is preferably 1-80 μm.

The described are merely preferred embodiments in the present invention. However, the structural features of the present invention are not limited thereto, and changes and modifications may be made to the described embodiments without departing from the scope of the invention as disposed by the appended claims.

What is claimed is:

1. A method of enhancing generation efficiency of patterned optical coating, comprising:
wafer cleaning process: cleaning a silicon wafer with a plurality of chips separated by scribe lines;
photoresist coating process: forming a photoresist layer the surface of said silicon wafer to cover the plurality of chips;
exposure and development (including dummy pattern) process: by using an optical exposure system to form line patterns of the photoresist layer on said silicon wafer;
optical coating process: coating an optical film on the surface of each of line pattern and the exposed chips; and
photoresist removal process: removing the line patterns of the photoresist layer by using a photoresist lift-off process and keep the coated optical film on the surface of chips;
characterized in that: in the exposure and development (including dummy pattern) process, when the line patterns of the photoresist layer are formed on said silicon wafer, a dummy pattern is also formed on the scribe lines around the chip as the lift-off start point of the photoresist removal process.

2. The method of enhancing generation efficiency of patterned optical coating as claimed in claim 1, wherein the width of the dummy pattern is 1-80 μm.

3. The method of enhancing generation efficiency of patterned optical coating as claimed in claim 1, wherein the dummy pattern is a sacrificial layer for implementing the photoresist removal process.

4. The method of enhancing generation efficiency of patterned optical coating as claimed in claim 3, wherein the dummy pattern can be a grid pattern, a square pattern, a circle pattern, a triangle pattern, or other patterns.
